(19) United States
(12) Patent Application Publication
(10) Pub. No.: US 2018/0006573 A1
(43) Pub. Date: Jan. 4, 2018

(54) Electrical Power Conversion Unit and Electrical Power Conversion Device

(71) Applicant: Hitachi, Ltd., Chiyoda-ku, Tokyo (JP)

(72) Inventors: Yukio HATTORI, Tokyo (JP); Hiroshi KAMIZUMA, Tokyo (JP); Daisuke MATSUMOTO, Tokyo (JP); Akira MIMA, Tokyo (JP); Ryouhei MIYAGAWA, Tokyo (JP)

(21) Appl. No.: 15/548,477

(22) PCT Filed: Mar. 4, 2015
(86) PCT No.: PCT/JP2015/056276

§ 371 Date: Aug. 3, 2017

(51) Int. Cl. H02M 7/217; H05K 7/20

(52) U.S. Cl. CPC H02M 7/217; H05K 7/209; H05K 7/20909

(57) ABSTRACT

An electrical power conversion unit is provided with: a circuit connecting part which includes a positive electrode conductor, a negative electrode conductor, and an alternating current conductor; a power semiconductor module connected to a specific side of the circuit connecting part; a fin that extends to the opposite side of the circuit connecting part with respect to the power semiconductor module; and a capacitor disposed at one end in the lengthwise direction of the circuit connecting part. A space in which a cooling fan is disposed is formed by an extending part and the fin, when the extending part is defined as a region, of the circuit connecting part, other than the portion at which the fin projects to the circuit connecting part, such region including one end that is opposite, via the fin, the one end where the capacitor is present.

### TECHNICAL FIELD

The present invention relates to an electrical power conversion unit and an electrical power conversion device.

### BACKGROUND ART

In the conventional electrical power conversion units, a technical advance in power semiconductors used in a power semiconductor module, which is a main component, increases a switching operation speed and decreases loss in semiconductors. This can down-size a cooling unit for cooling the power semiconductor module, which provides down-sizing the electrical power conversion unit. Particularly, it is desired that an installation area is small because a UPS (Uninterruptible Power Supply) having the electrical power conversion unit is installed for use of a data center at an area in the vicinity of a city having a high land price. Further, to efficiently use the installation area, the electrical power conversion units in the UPS are installed in such a state that sides of the adjoined electrical power conversion units are arranged close to each other and that the rear face is close to a wall. Accordingly, it is desirable that devices or components, etc installed in the unit are allowed to be accessed from a front face of the unit in consideration of workability during maintenance.

JP H08-294266 (Patent document 1) is disclosed which is a background of the technical field. This document disclosed that a power module unit in which a plurality of semiconductor elements are installed on a cooling block having a cooling device such as cooling fins and a capacitor unit are housed in two sections arranged in a casing of the electrical power conversion unit, respectively. This can enhance the workability. Further, the unit has a fan installed on an upper part of the power module unit to cool the cooling device.

### PRIOR ART

### Patent Document

Patent Document 1: JP H08-294266 A

### SUMMARY OF INVENTION

### Problem to be Solved by Invention

However, the electrical power conversion unit disclosed in Patent Document 1 has a size in the height direction of the electrical power conversion unit becomes large because the capacitor unit, the power module unit, and the fan are piled in the height direction, a height of the power conversion unit becomes large.

The present invention aims to down-size the whole of the power conversion unit by reducing sizes of the power conversion unit.

### Means for Solving Problem

To solve the problem, according to an embodiment of the present invention, there is provided an electrical power conversion device comprising:

a circuit connecting part including a positive electrode conductor, a negative electrode conductor, and AC conductors;

a power semiconductor module connected to a predetermined side of the circuit connecting part;

a fin extending to a side opposite to the circuit connecting part across the power semiconductor module;

a capacitor provided on one end of the circuit connecting part in a longitudinal direction of the circuit connecting part;

wherein assuming that a region out of the circuit connecting part other than a part of the circuit connecting part on which the fin is projected includes another end of the circuit connecting part on a side opposite across the fin to the one end at which the capacitor is disposed is defined as an extending part, a space is formed by the extending part and the fin

### Advantageous Effect of Invention

According to an embodiment of the present invention, it is possible to down-size the electrical power conversion device with reduction in size of the power conversion device.

### BRIEF DESCRIPTION OF DRAWINGS

FIG. 1 is a block diagram of a UPS according to an embodiment of the present invention.

FIG. 2 is a circuit diagram of a converter 11.

FIG. 3 is a circuit diagram of an inverter 12.

FIG. 4 is a circuit diagram of a boost chopper 13.

FIG. 5 is a circuit diagram of an electrical conversion unit 101.

FIG. 6 is a perspective view of an electrical power conversion section 2a.

FIG. 7 is a right side view of the electrical power conversion unit 101.

FIG. 8 is a perspective view of the electrical power conversion unit 101.

FIG. 9 is a perspective exploded view showing a front face of the electrical power conversion unit 101.

FIG. 10 is a perspective exploded view showing a rear face of the electrical power conversion unit 101 according to the embodiment of the present invention.

FIG. 11 is a right side view showing configuration of the fan 201 in the electrical power conversion section 2a.

FIG. 12 is a right side view of ventilation holes 206, 207 installed in a fan duct 205.

### MODES FOR CARRYING OUT INVENTION

Hereinbelow embodiments of the present invention are described below referring to the drawings.

A UPS (Uninterruptible Power Supply) is exemplified in the embodiment of the present invention.

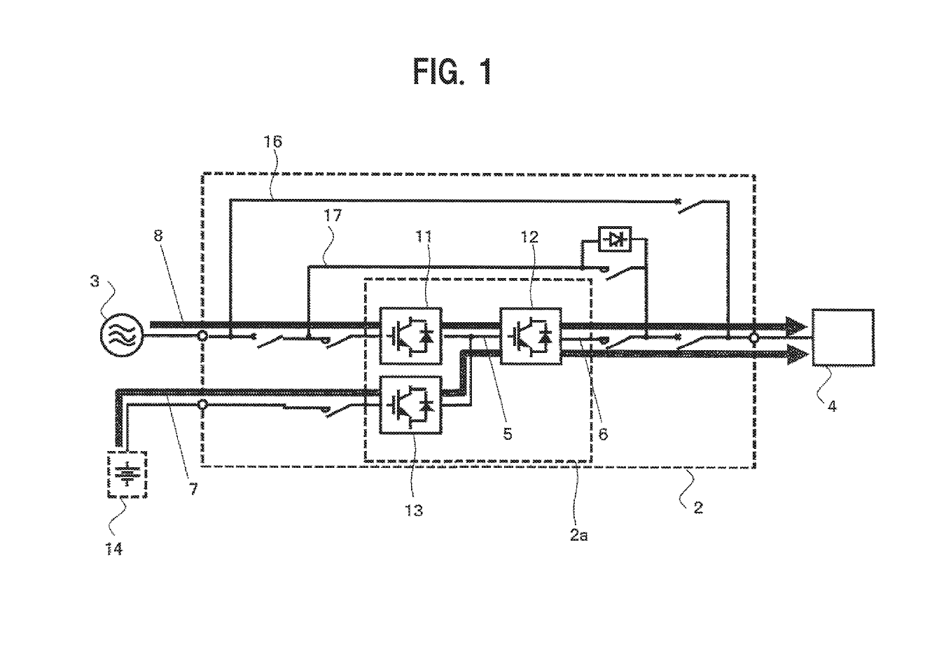

FIG. 1 is a block diagram of the UPS according to the embodiment of the present invention.

The UPS 2 uses a normal inverter feed system which can continue electric power supply without interruption during a power fail. It is noted that the present invention is applicable to not only the normal inverter feed system but also other system such as normal commercial power feed system.

A three-phase alternating commercial power source 3 supplies electric power to a load 4 via a power converter 11 and an inverter 12 in a normal operation as shown by a path 8. The power converter 11 converts three-phase power from the commercial power source 3 into a DC power to be supplied to the inverter 12 through a path 5. The inverter 12 converts the DC voltage 5 into three-phase AC power and supplies the three-phase AC power via a path 6. This can supply a power equivalent to the general commercial power source stable by control by the power converter 11 and the inverter 12, though a voltage variation such as an instantaneous voltage drop occurs at the commercial power source 3.

On the other hand, upon power failure, the power is supplied from a battery 14 to the load 4 via the inverter 12 in the state that the inverter 12 is activated. Accordingly the UPS 2 can supply the power to the load 4 in an uninterrupted manner. In the embodiment, to decrease a volume of the UPS 2, a total voltage of the battery 14 is made sufficiently smaller than a DC voltage applied to the inverter 12. Accordingly, the UPS 2 according to the present embodiment supplies the DC voltage having a low voltage value which is output by discharging of the battery 14 to a booster chopper 13 as shown by a path 7. When there is no restriction in volume of the UPS 2, the booster chopper 13 is omitted but the battery 14 for high voltage which can supply a desired DC voltage is installed.

Hereinbelow combination of the power converter 11, the inverter 12, and the booster chopper 13 is referred to as a power conversion section 2a.

The UPS 2 may further include a cooling device such as a cooling fan to air-cool the power conversion section 2a.

A bypass circuit 17 bypasses the power conversion section 2a according to a command to directly connect the commercial power source 3 to the load 4. A maintenance bypass circuit 16 bypasses the power conversion section 2a and the bypass circuit 17 to directly connect the commercial power source 3 to the load 4 according to a command for maintaining the power conversion section 2a and the bypass circuit 17.

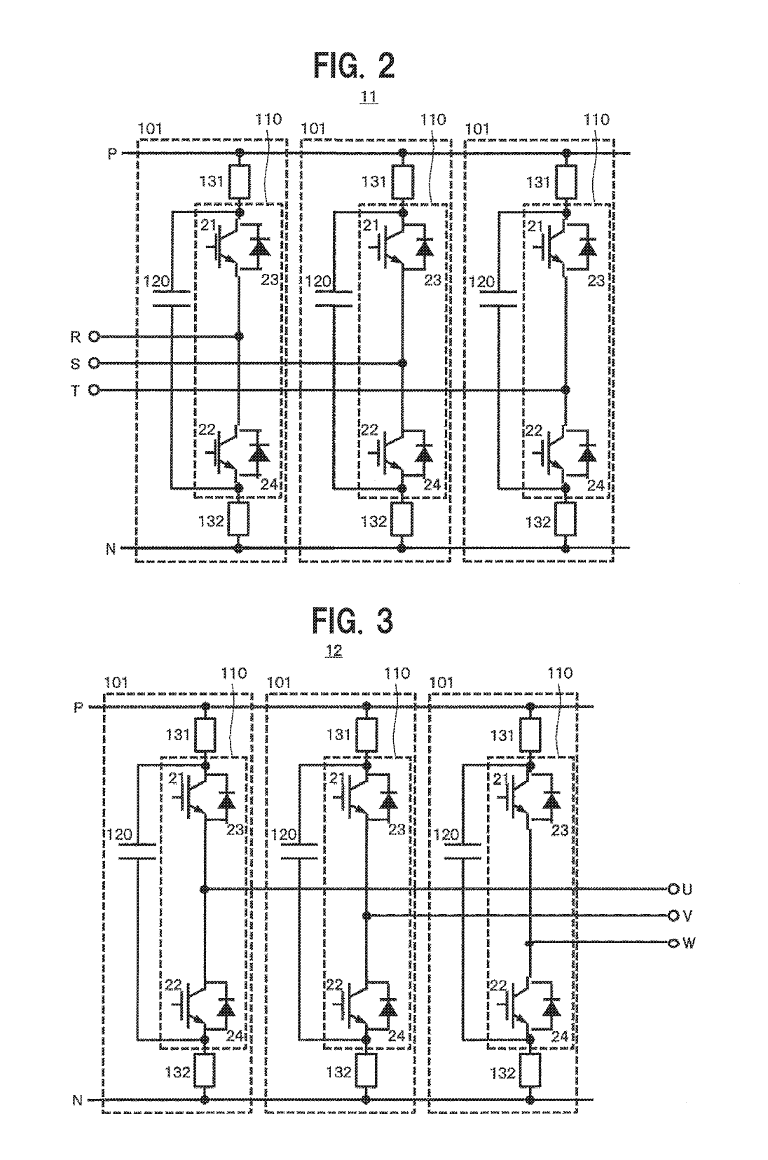

FIG. 2 is a circuit diagram of the power converter 11.

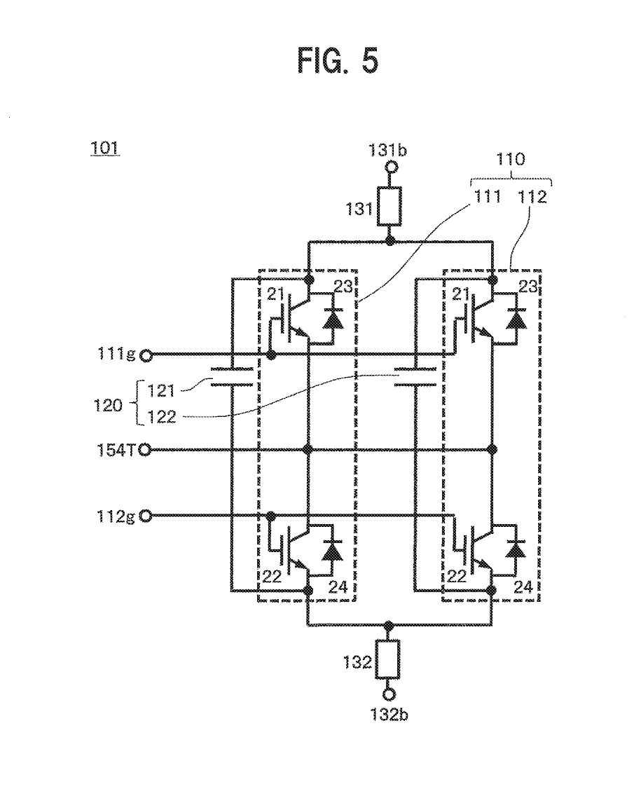

The three-phase AC power from the commercial power source 3 is supplied to AC terminals R, S, T of the power converter 11 and a current of each of the R-, S-, and T-phases is rectified by a switching element 21 and a rectifying element 23 in an upper arm and a switching element 22 and a rectifying element 24 using a capacitor group 120 and the DC power is outputted at DC terminals P, N. In the embodiment, IGBTs (Insulated Gate Bipolar Transistor) are used as the switching elements 21, 22, and diodes are used as the rectifying elements 23, 24. However, the present invention is not limited to these and other elements are applicable. A structure of a power conversion unit 101 will be described later with reference to FIG. 5.

FIG. 3 is a circuit diagram of the inverter 12.

The DC voltage converted by the power converter 11 or the booster chopper 13 is supplied to the DC terminals P, N of the inverter 12 and the DC power is converted into an AC power at the path 6 by the switching element 21 and the rectifying element 23 in the upper arm, the switching element 22 and the rectifying element 24 in the lower arm, and the capacitor group 120 and the AC power is outputted at AC terminals U, V, W. Three-phase AC power outputted by the AC terminals U, V, W is supplied to the load 4.

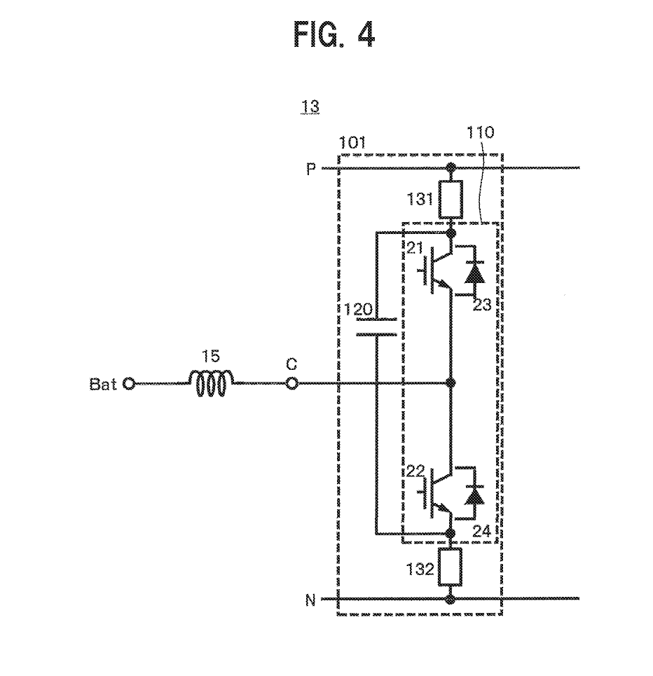

FIG. 4 is a circuit diagram of the booster chopper 13.

An output of the battery 14 is supplied to an input terminal Bat. While the switching element 22 in the lower arm is turned ON, energy is stored in a reactor 15 connected between the input terminal Bat and an AC terminal C. Next, when the switching element 22 in the lower arm turns OFF, a counter emf generated by the reactor 15 turns on the rectifying element 23. Accordingly, a sum voltage of the DC voltage outputted by the battery 14 and the counter efm by the reactor 15 appears at the DC terminals P, N of the booster chopper 13, and a boosted DC voltage is outputted.

As described above, any one of the power converter 11, the inverter 12, and the booster chopper 13 installed in the UPS 2 includes at least one basic circuit. The basic circuit includes: a power semiconductor module group 110, which is a two-level half bridge circuit in which the upper arm including the switching element 21 and the rectifying element 23 and the lower arm including the switching element 22 and the rectifying element 24, are connected in series; the capacitor group 120; a fuse 131 on a positive terminal side; and a fuse 132 on a negative terminal side. A conversion circuit having three or more levels may be used in place of the two-level half bridge circuit.

In the present embodiment, the basic circuit is provided by the power conversion unit 101, and the power converter 11, the inverter 12, and the booster chopper 13 are provided by combination of the power conversion units 101. This contributes to common parts utilization regarding types of the parts used in the power conversion section 2a as well as makes assembling and maintenance of the power conversion section 2a easy.

FIG. 5 is a circuit diagram of an electrical conversion unit 101 according to the embodiment of the present invention.

In the power conversion unit 101, a power semiconductor module group 110 is provided by connecting a power semiconductor module 111 of a 2in1 type forming upper and lower arms in parallel to a power semiconductor module 112. Further, the capacitor group 120 is provided by connecting a first capacitor 121 in parallel to a second capacitor 122. This provides the power semiconductor module group 110 and a capacitor group 120 corresponding to a power demanded for the power conversion unit 101 using a plurality of the power semiconductor modules and a plurality of capacitors.

Further, in the power conversion unit 101, the fuse 131 is connected in series to a positive terminal side of a power semiconductor module group 110 and the capacitor group 120, and the fuse 132 is connected to a negative terminal side of the power semiconductor module group 110 and the capacitor group 120. A second terminal 131b of the fuse 131 corresponds to the P terminals of the power converter 11, the inverter 12, and the booster chopper 13. A second terminal 132b of the negative terminal side fuse 132 corresponds to the N terminals of the power converter 11, the inverter 12, and the booster chopper 13. Fuses 131, 132 are provided in the power conversion unit 101 which increases a reliability of the power conversion unit 101 upon a short circuit failure. In a case where the power conversion unit 101 can be disconnected by a breaker, either or both of the fuse 131 and the fuse 132 may be omitted.

Power semiconductor modules 111, 112 each include a switching element and the rectifying element 23 in the upper arm and the switching element 22 and the rectifying element 24 in the lower arm. Junctions between upper arms and lower arms of the power semiconductor modules 111 and 112 are connected to an external AC terminal 154T. Gate terminals of the switching elements 1 in the respective upper arms of the power semiconductor modules 111, 112 are connected to the gate terminal 111g. Gate terminals of the switching elements 22 in the lower arms of the power semiconductor modules 111, 112 are connected to a gate terminal 112g.

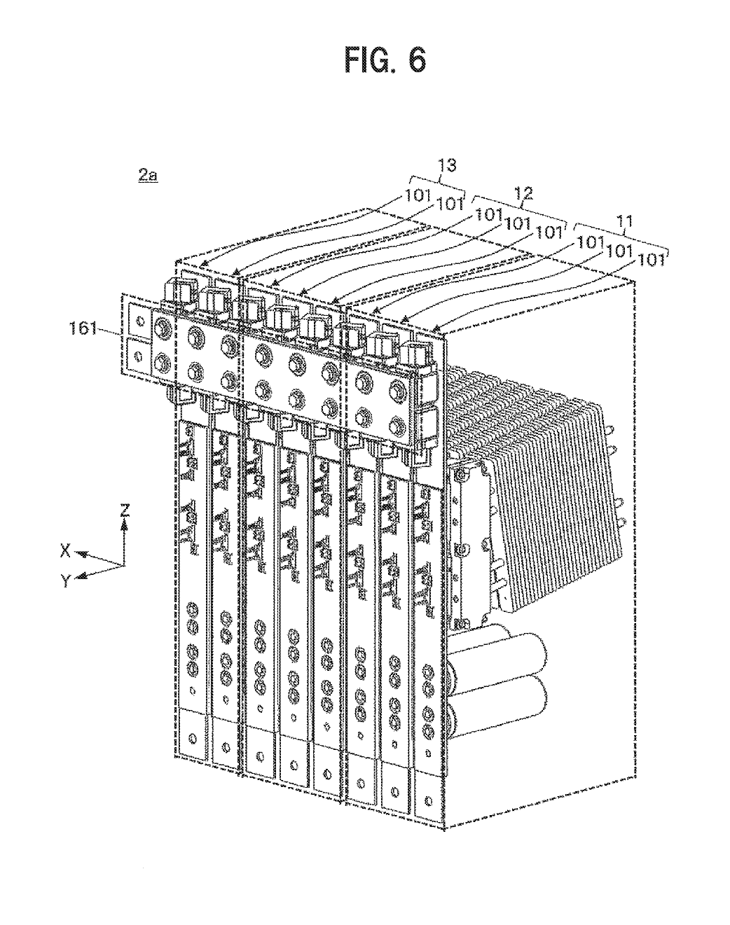

FIG. 6 is a perspective view of an electrical power conversion section 2a.

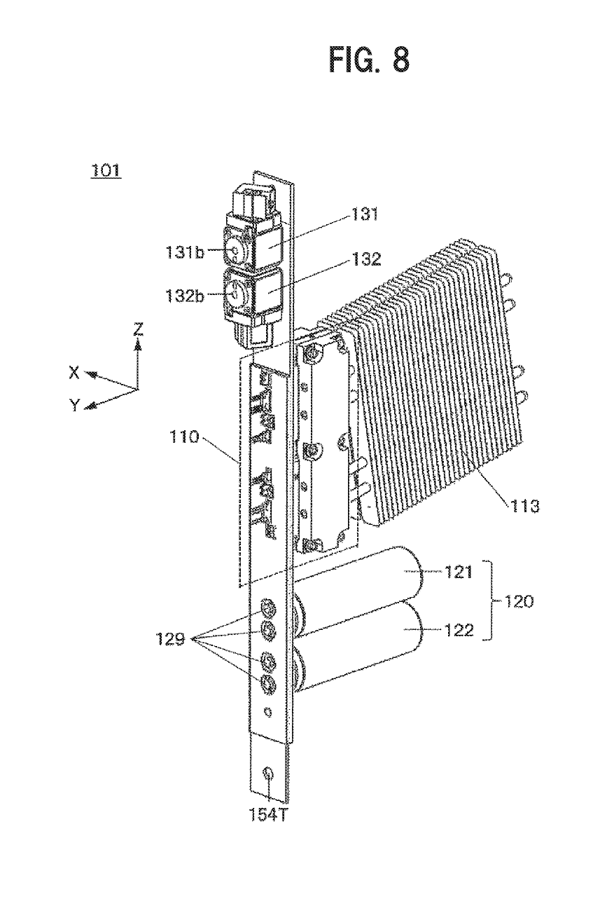

Hereinbelow, X axis, Y axis, and Z axis are determined to be coordinates for the UPS 2 as shown in FIG. 6. In the embodiment, the Y axis direction is a front direction of the UPS 2 and the Z axis direction is an upper direction of the UPS 2, and the X axis direction is a left of the UPS 2. The power conversion section 2a is installed in a casing (not shown) of the UPS 2, and an opening and closing door (not shown), which is opened upon maintenance of the UPS 2, is provided at a part in the Y-axis direction of the power conversion section 2a, i.e., at the front face of the casing of the UPS 2. Opening the opening and closing door allows easy access to the front face of the power conversion section 2a. As another embodiment, there is a case where wind flow in one of the Y directions (a side of the rear wall). In this case, the conversion unit shown in FIG. 8 may be rotated on the X axis by 90 degrees (a type of UPS for 400V system).

The power conversion section 2a includes a plurality of the power conversion units 101 arranged in the X-axis direction. The power converter 11 includes three power conversion units 101 corresponding to three phases of the commercial power source, respectively. Similarly, the inverter 12 includes three power conversion units 101 corresponding to the three phases, respectively. The booster chopper 13 includes two power conversion units 101 connected in parallel. The booster chopper 13 may include one of the power conversion unit 101. When the power demanded for the booster chopper 13 exceeds a rated power of the power semiconductor module group 110 installed in the power conversion unit 101, connecting N of the power conversion units 101 in parallel provides the allowable power multiplied by N. Further, similarly, each of the power converter 11 and the inverter 12 may include a plurality of the power conversion units 101 connected in parallel per one phase as required.

A plurality of the power conversion units 101 in the power conversion section 2a are connected in parallel through the unit junction 161. A longitudinal direction of each of the power conversion units 101 is the Z direction, and a plurality of the power conversion units 101 are arranged in the X direction. A longitudinal direction of the unit junction 161 is in the X direction, and the unit junction 161 is disposed extending in +Y direction across a plurality of the power conversion units 101. In other words, the longitudinal direction of the power conversion units 101 intersects the longitudinal direction of the unit junction 161. This provides a higher efficient arrangement of a plurality of the power conversion units 101 in a limited volume.

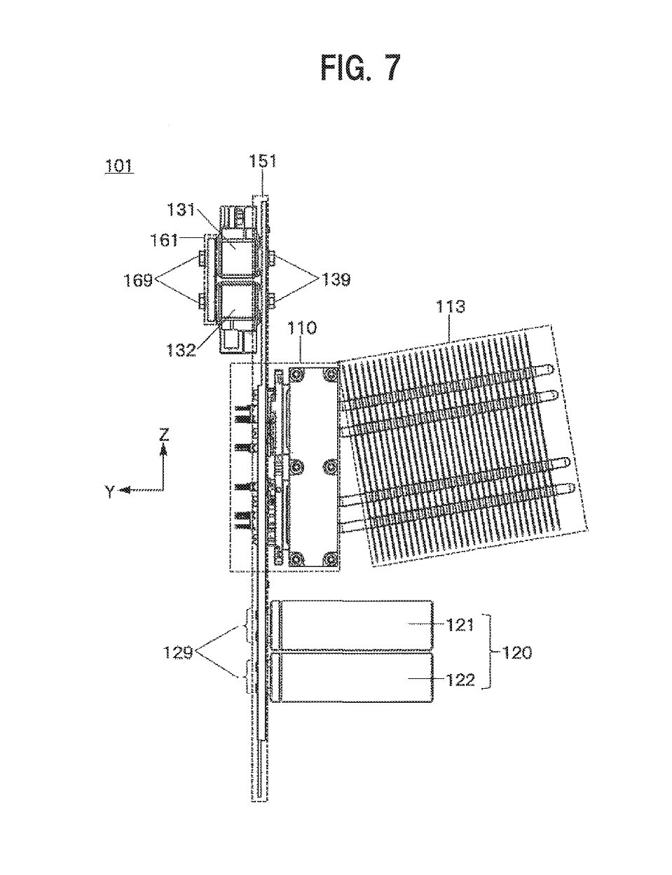

FIG. 7 is a right side view of the electrical power conversion unit 101.

The power conversion unit 101 includes the power semiconductor module group 110, the capacitor group 120, the fuse 131 and the fuse 132, and a circuit connecting part 151 for electrically connecting them. Cooling fins 113 are installed on a rear face (−Y direction) of the power semiconductor module group 110 to cool the power semiconductor module group 110. These components are arranged in the lower direction (−Z direction) in an order of the fuses 131, 132, the power semiconductor module group 110, and the capacitor group 120. Adjoining the power semiconductor module group 110 to the capacitor group 120 can decrease a parasitic inductance generated at the circuit connecting part 151 connecting the power semiconductor module group 110 to the capacitor group 120, so that a surge voltage generated upon switching can be reduced. Further, as described later, because an impedance from the power semiconductor module group 110 in its own power conversion unit 101 to the capacitor group 120 in the adjoining power conversion unit 101 can be made smallest, the capacitor group 120 of another power conversion unit 101 can be also efficiently used in addition to the capacitor group 120 of its own the power conversion unit 101. As a result, a capacity of the capacitor group 120 used per one power conversion unit 101 can be reduced, which reduces a volume of the power conversion unit 101.

The power semiconductor module group 110 and the capacitor group 120, both having terminals protruded in the front (+Y direction), are arranged in the rear direction (−Y direction) from the circuit connecting part 151. This arrangement positions all the terminals of the power semiconductor module group 110 and the capacitor group 120 at the front face, which makes inspection of the terminal part upon the maintenance or mounting and removing operations easy.

FIG. 8 is a perspective view of the electrical power conversion unit 101 according to the embodiments of the present invention.

The fuses 131, 132 each include one terminal in a rear direction (−Y direction) and another terminal in the front direction (+Y) direction. Further the fuses 131, 132 are arranged in the front direction (+Y direction) from the circuit connecting part 151. In other words, a first terminal 131a of the fuse 131 on a positive terminal side and a first terminal 132a of the fuse 132 on the negative terminal side face the rear direction (−Y direction) and connected to the circuit connecting part 151 with a mounting screw 139 shown in FIG. 7. On the other hand, the second terminal 131b of the fuse 131 and a second terminal 132b on the negative terminal side face the front direction (+Y direction). This arrangement provides a good accessibility to the front face upon assembling and the maintenance and increase an operation ability because the second terminal 131b of the fuse 132 on the positive terminal side which is a terminal for connecting its own power conversion unit 101 to another power conversion unit 101 and the second terminal 132b for the fuse 132 on the negative terminal side are located on the front face of the UPS 2. As described above, there are three external terminals which the power conversion unit 101 has, i.e., the second terminal 131b for the fuse 131 on a positive terminal side, which is connected to the unit junction 161 for connection to another one of the power conversion units 101, and the external AC terminal 154T provided to the circuit connecting part 151.

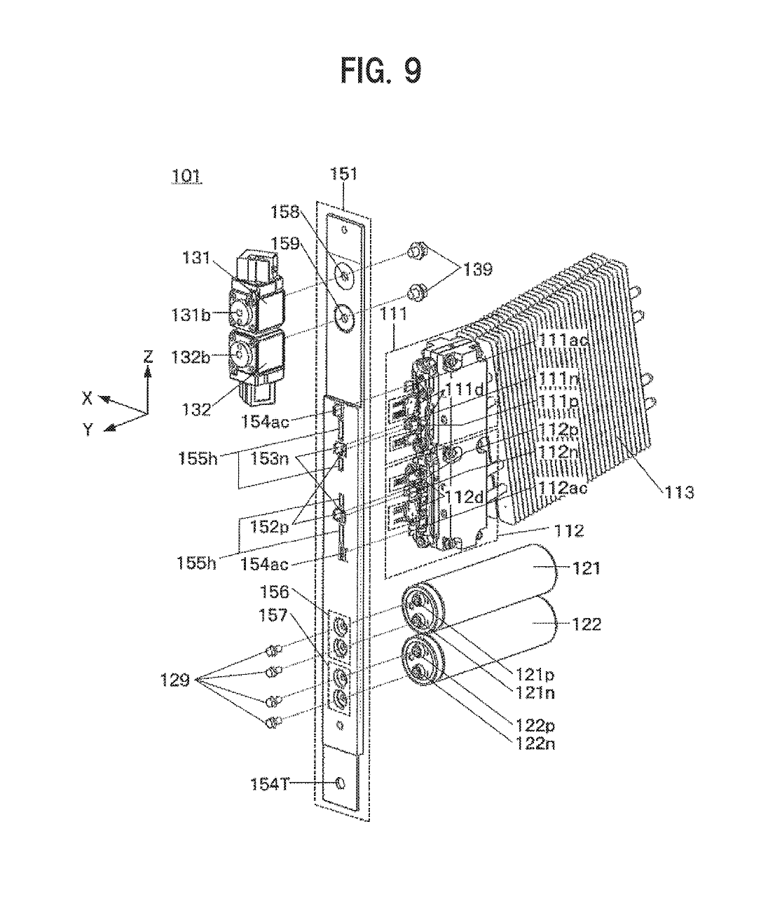

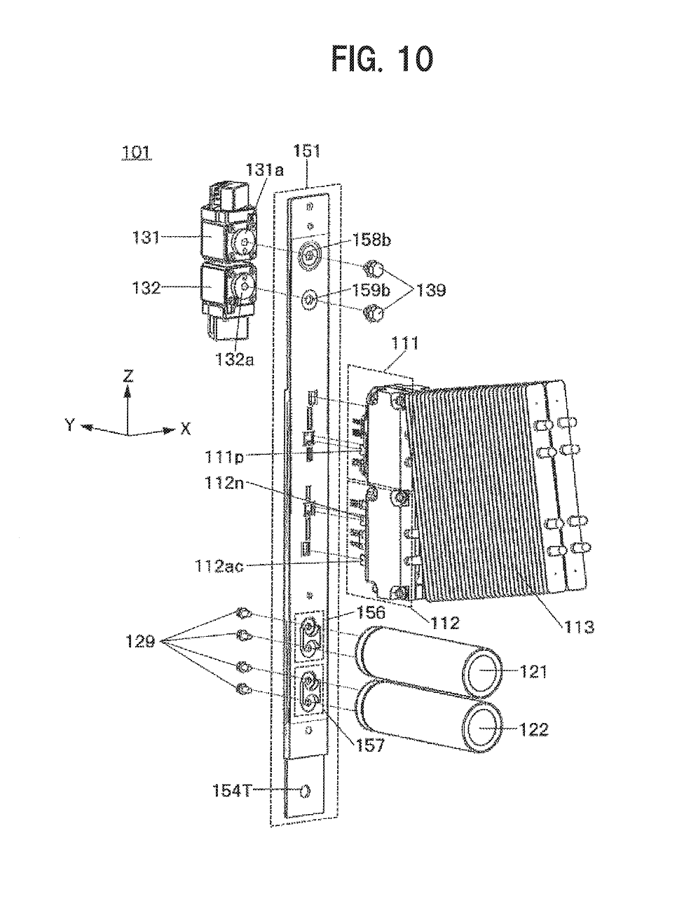

FIG. 9 is a perspective exploded view showing a front face of the electrical power conversion unit 101 according to the embodiments of the present invention. FIG. 10 is a perspective exploded view showing a rear face of the electrical power conversion unit 101 according to the embodiments of the present invention.

In the embodiment, the power semiconductor module group 110 includes the power semiconductor module 111 and the power semiconductor module 112, each of which is a two-level half bridge circuit (2in1), and which are connected in parallel. The number of parallel connection of the power semiconductor modules in the power conversion unit 101 is determined to be a necessity minimum to allow the power based on a module having the minimum power in a lineup of UPSs and other power converters using the power conversion unit 101. This is because a desired power can be obtained by parallel connection of the power conversion units 101 for a unit requiring a larger electric power.

In consideration of this, the number of parallel-connected power semiconductor modules is two in the embodiment.

The power semiconductor module 111 and the power semiconductor module 112 include positive terminals 111p, 112p, negative terminal 111n, 112n, AC terminals 111ac, 112ac, and control terminals 111d, 112d, respectively. The control terminal groups 111d, 112d include gate terminals 111g, 112g, respectively.

The positive terminals 111p, 112p in the power semiconductor module group 110 are connected to a connection terminal 152p of a positive polarity in the circuit connecting part 151. In the power semiconductor module group 110, the negative terminal 111n and a negative terminal 112n are connected to a negative terminal 153n in the circuit connecting part 151. The AC terminals 111ac, 112ac in the power semiconductor module group 110 are connected to a connection terminal 154ac connected to the external AC terminal 154T. The positive terminals 111p, 112p, the negative terminals 111n, 112n, the AC terminals 111ac, 112ac are connected to corresponding parts in the circuit connecting part 151 by jointing method such as welding. Further, the connection may be performed by threads or clips.

To suppress a difference between a distance from the capacitor group 120 to the positive terminal 111p and the negative terminal 111n of the power semiconductor module 111 and a distance from the capacitor group 120 to the positive terminal 112p and the negative terminal 112n of the power semiconductor module 112, an arrangement of the positive terminal 112p and the negative terminal 112n in the power semiconductor module 112 is inverted from an arrangement of the positive terminal 111p and the negative terminal 111n in the X-axis direction in the power semiconductor module 111. Further, the positive terminal 111p and the negative terminal 111n of the power semiconductor module 111 are brought close to the positive terminal 112p and the negative terminal 112n in the power semiconductor module 112 and facing each other. This arrangement decreases the differences in impedance between the power semiconductor module 111 and the power semiconductor module 112 and between the first capacitor 121 and the second capacitor 122, which enhances evenness in intensities of currents flowing in the power semiconductor module 111 and the power semiconductor module 112.

A positive terminal 121p and a negative terminal 121n which the first capacitor 121 has are mounted on a connection part 156 installed at the circuit connecting part 151 with capacitor mounting screws 129. Similarly, a positive terminal 122p and a negative terminal 122n which the second capacitor 122 has are mounted on a connection part 157 installed at the connection part 157 with capacitor mounting screws 129.

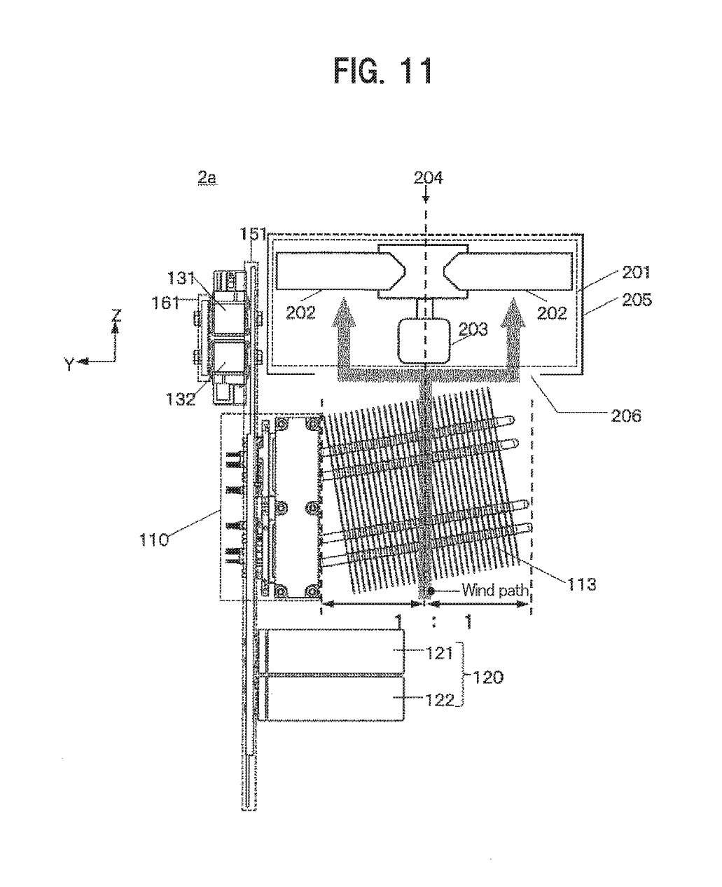

FIG. 11 is a right side view showing a configuration of the fan 201 in the electrical power conversion section 2a according to the embodiments of the present invention.

A fan 201 is a device for cooling the cooling fins 113 installed to the power semiconductor module group 110 for cooling using wind and includes fan blades 202 and a fan motor 203. The fan 201 is located in a space which is above (+Z direction) the power semiconductor module group 110 and the cooling fins 113 (+Z direction) and behind the circuit connecting part 151 (−Y direction). More specifically, there is the space formed at a part of the circuit connecting part 151 extending in the upper direction (+Z direction) from a part of the circuit connecting part 151 onto which the cooling fins 113 are projected. The fan is installed in the space, which utilizes the space, which can reduce the volume of the UPS 2 by a volume corresponding to the fan. Further, the casing is designed and a cooling mechanism are provided so that wind blows in an upper direction (+Z direction) to cool the cooling fin 113 on the rear side of the circuit connecting part 151. Accordingly, the cooling fin 113 locate on downstream side of a wind path from the capacitor group 120, i.e., on an upper side of the capacitor group 120, so that the capacitor group 120 does not receive heat radiation from the cooling fin 113.

Further, a rotation axis 204 of the fan motor 203 in the fan motor 203 locates at the position where a center point of the length of the cooling fin 113 in Y-axis direction. This arrangement provides symmetrical distribution of blow rates of the wind passing through the cooling fins 113 and evenly during discharging or sucking. Air flow rates are evenly distributed over the cooling fin 113. This improves a cooling performance and provides increase in a life time of the fan 201.

A fan duct 205 covering the fan is formed around the fan 201. The fan duct 205 surrounds the fan blades 202 and the fan motor 203 which the fan 201 has, to control the wind path and the wind flow rate to cool the cooling fins 113 to be a cooling target and other heating elements. The fan duct 205 has a ventilation hole 206 at an area facing the cooling fin 113. Further, a wind path is made on a face of the fan duct 205 opposite to a fin 133. This forms a wind path for cooling the cooling fins 113.

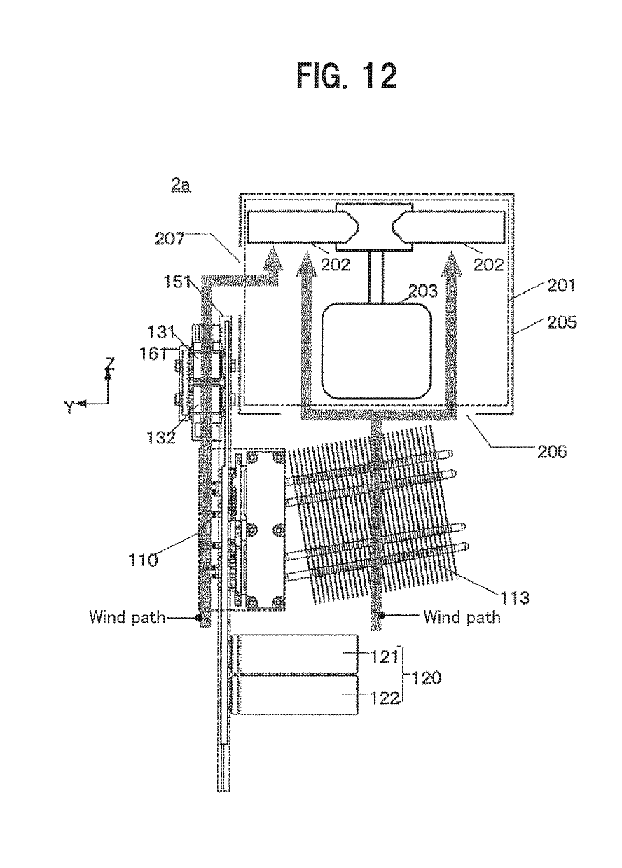

FIG. 12 is a right side view of ventilation holes 206, 207 installed in a fan duct 205.

The fan duct 205 includes the first ventilation hole 206 on a side facing the cooling fin 113 and a second ventilation hole 207 on a side facing the circuit connecting part 151. This provides a wind path for cooling the cooling fins 113 and a wind path for cooling the circuit connecting part 151, the unit junction 161, and the fuses 131, 132.

Further, the second ventilation hole 207 is formed to have opening ends at a position having a maximum coordinate value in the Z direction among the circuit connecting part 151, the unit junction 161, the fuses 131, 132 and a position at the minimum coordinate value of the fan blades 202 in the Z direction.

The power converter unit is installed such a direction that the Z axis is vertical to the ground, so that it is assumed that the wind blows from the ground in the direction to the ceiling. Further, it can be assumed that Y axis is vertical to the ground, so that it is assumed that a wind blows from a front face to the back face of the power converter.

The present invention is not limited to the above-described embodiment, but can be modified in various modes without departure from a spirit of a subject matter.

### DESCRIPTION OF REFERENCE SYMBOLS

1 electrical power conversion device
2 UPS (Uninterruptible Power Supply)
11 power converter
12 inverter
13 booster chopper
101 power conversion unit
110 power semiconductor module group
111 power semiconductor module
113 cooling fin
120 capacitor group
121, 122 capacitor
131 fuse
151 circuit connecting part
152 positive electrode conductor
153 negative electrode conductor
154 AC conductor
154T external AC terminal
155 insulator
202 fan blade
203 fan motor
204 rotation axis
205 fan duct
206 first ventilation hole
207 second ventilation hole

1. An electrical power conversion unit comprising:
a circuit connecting part including a positive electrode conductor, a negative electrode conductor, and AC conductors;
a power semiconductor module connected to a predetermined side of the circuit connecting part;
a fin extending to a side opposite to the circuit connecting part across the power semiconductor module;
a capacitor provided on one end of the circuit connecting part in a longitudinal direction of the circuit connecting part;
wherein assuming that a region out of the circuit connecting part other than a part of the circuit connecting part on which the fin is projected includes another end of the circuit connecting part on a side opposite across the fin to the one end at which the capacitor is disposed is defined as an extending part, a space is formed by the extending part and the fin.

2. The electrical power conversion unit as claimed in claim 1, wherein a rotation axis of a fan motor provided in the fan is at a position including a middle point of an extending line of the fin.

3. The electrical power conversion unit as claimed in claim 1, wherein a fan duct is provided to cover the fan includes a first ventilation hole on a face thereof facing the fin and a second ventilation hole on a face thereof facing the circuit connecting part.

4. The electrical power conversion unit as claimed in claim 3,
wherein the fan comprises a fan blade that exhausts or sucks wind, and
wherein the second ventilation hole is located between an end of the extending part and a lower end in a height direction of the fan blade.

5. The electrical power conversion unit as claimed in claim 1, further comprising a fuse provided at a region of the extending part on a side opposite across the circuit connecting part to the side at which the power semiconductor module is provided.

6. The electrical power conversion unit as claimed in claim 1, wherein the fan blows wind from a side of the capacitor to the power semiconductor module.

7. An electrical power conversion device comprising:
a power conversion unit including:
a circuit connecting part including a positive electrode conductor, a negative electrode conductor, and AC conductors;
a power semiconductor module connected to a predetermined side of the circuit connecting part;
a fin extending to a side opposite to the circuit connecting part across the power semiconductor module;
a capacitor provided to an end of the circuit connecting part in a longitudinal direction of the circuit connecting part; and
a cooling fan, wherein assuming that a region out of the circuit connecting part other than a part of the circuit connecting part on which the fin is projected includes another end of the circuit connecting part on a side opposite across the fin to the one end at which the capacitor is disposed is defined as an extending part, the cooling fan is disposed in a space enclosed by the extending part and the fin.
